(19) United States
(12) Patent Application Publication
(10) Pub. No.: US 2021/0280523 A1
(43) Pub. Date: Sep. 9, 2021

(54) INTEGRATED CIRCUIT (IC) PACKAGES EMPLOYING SPLIT, DOUBLE-SIDED METALLIZATION STRUCTURES TO FACILITATE A SEMICONDUCTOR DIE ("DIE") MODULE EMPLOYING STACKED DICE, AND RELATED FABRICATION METHODS

(71) Applicant: QUALCOMM Incorporated, San Diego, CA (US)

(72) Inventors: Hong Bok We, San Diego, CA (US); Aniket Patil, San Diego, CA (US); Marcus Hsu, San Diego, CA (US); David Fraser Rae, San Diego, CA (US)

(21) Appl. No.: 16/916,339

(22) Filed: Jun. 30, 2020

Related U.S. Application Data
(60) Provisional application No. 62/984,936, filed on Mar. 4, 2020.

(51) Int. Cl. H01L 23/538; H01L 23/31; H01L 23/00; H01L 21/48; H01L 21/56

(52) U.S. Cl. CPC H01L 23/5389; H01L 23/3128; H01L 23/5383; H01L 21/565; H01L 23/562; H01L 21/4853; H01L 21/4857; H01L 23/5386

(57) ABSTRACT

Integrated circuit (IC) packages employing split, double-sided IC metallization structures to facilitate a semiconductor die (“IC die”) module employing stacked dice, and related fabrication methods are disclosed. Multiple IC dice in the IC package are stacked and bonded together in a back-to-back, top and bottom IC die configuration in an IC die module, which can minimize the overall height of the IC package. The metallization structure is split between separate top and bottom metallization structures adjacent to respective top and bottom surfaces of the IC die module to facilitate die-to-die and external electrical connections to the dice. The top and bottom metallization structures can be double-sided by exposing substrate interconnects on respective inner and outer surfaces for respective die and external electrical interconnections. In other exemplary aspects, the top and bottom metallization structures can include redistribution layers (RDLs) to provide increased electrical conductivity between die interconnects and substrate interconnects.

### PRIORITY APPLICATION

The present application claims priority under 35 U.S.C. § 119(e) to U.S. Provisional Patent Application Ser. No. 62/984,936, filed Mar. 4, 2020 and entitled “INTEGRATED CIRCUIT (IC) PACKAGES EMPLOYING SPLIT, DOUBLE-SIDED METALLIZATION STRUCTURES TO FACILITATE A SEMICONDUCTOR DIE (“DIE”) MODULE EMPLOYING STACKED DICE, AND RELATED FABRICATION METHODS,” which is incorporated herein by reference in its entirety.

### BACKGROUND

### I. Field of the Disclosure

The field of the disclosure relates to integrated circuit (IC) packages that include one or more semiconductor dice attached to a package structure that provides an electrical interface to the semiconductor dice.

### II. Background

Integrated circuits (ICs) are the cornerstone of electronic devices. ICs are packaged in an IC package, also called a “semiconductor package” or “chip package.” The IC package includes one or more semiconductor dice as an IC(s) that are mounted on and electrically coupled to a package substrate to provide physical support and an electrical interface to the semiconductor die(s). The package substrate may be an embedded trace substrate (ETS), for example, that includes embedded electrical traces in one or more dielectric layers and vertical interconnect accesses (vias) coupling the electrical traces together to provide electrical interfaces between the semiconductor die(s). The semiconductor die(s) is mounted to and electrically interfaced to interconnects exposed in a top layer of the package substrate to electrically couple the semiconductor die(s) to the electrical traces of the package substrate. The semiconductor die(s) and package substrate are encapsulated in a package material, such as a molding compound, to form the IC package. The IC package may also include external solder balls in a ball grid array (BGA) that are electrically coupled to interconnects exposed in a bottom layer of the package substrate to electrically couple the solder balls to the electrical traces in the package substrate. The solder balls provide an external electrical interface to the semiconductor die(s) in the IC package. The solder balls are electrically coupled to metal contacts on a printed circuit board (PCB) when the IC package is mounted to the PCB to provide an electrical interface between electrical traces in the PCB to the IC chip through the package substrate in the IC package.

### SUMMARY OF THE DISCLOSURE

Aspects disclosed herein include integrated circuit (IC) packages employing split, double-sided metallization structures to facilitate a semiconductor die (“IC die”) module employing stacked dice. Related chip packages and methods of fabricating the IC package are also disclosed. The IC package includes multiple semiconductor dice (also referred to as “IC dice”) mounted on a metallization structure. The metallization structure may be a package substrate or redistributed layers (RDLs) as examples, and can include one or more metal or interconnect layers of electrical traces for signal routing and vertical interconnect accesses (vias) to couple electrical traces together between different layers. Die interconnects (e.g., conductive pads) on a bottom, active surface of the IC die(s) are mounted on and electrically coupled to substrate interconnects exposed on an external surface of a metallization structure to electrically couple the IC die to the electrical traces in a metallization structure. The metallization structure includes one or more dielectric layers that contain a routing layer of electrical traces that can be electrically coupled to electrical traces in an adjacent dielectric layer through vertical interconnect accesses (vias) External package interconnects, such as solder balls, are provided on an external surface of a metallization structure and mounted to a circuit board to provide external electrical signal access to IC dice.

In exemplary aspects, to facilitate shrinking the overall height of the IC package to conserve area, the multiple IC dice in the IC package are stacked and bonded together in a back-to-back, top and bottom IC die configuration in an IC die module in the IC package. However, this orients the active areas of the stacked IC dice on opposite sides of the IC die module. Thus, to facilitate die-to-die and external electrical connections to the IC dice stacked in the back-to-back configuration, the metallization structure of the IC package is split between separate top and bottom metallization structures adjacent to respective top and bottom surfaces of the IC die module. The top metallization structure has an inside surface that has exposed substrate interconnects for electrical connection to die interconnects on the top side of the bottom IC die. The bottom metallization structure also has an inside surface that has exposed substrate interconnects for electrical connection to die interconnects on the bottom side of the top IC die. The metallization structures of the IC package being split between the top and bottom metallization structures mounted on opposing sides of the IC die module may allow the combined thickness of the top and bottom metallization structures to be reduced without risking warpage or mechanical instability. The thickness of a single metallization structure in an IC package having IC dice mounted to opposite sides of the single metallization structure may require additional dielectric layers, thus leading to an overall thicker metallization structure to avoid warpage or mechanical instability. The metallization structures of the IC package being split between the top and bottom metallization structures mounted on opposing sides of the IC die module also provides a symmetrical structure for the IC package and IC die module.

In other exemplary aspects, the top and bottom metallization structures are double-sided in that both also include exposed substrate interconnects on their respective outside surfaces that can be electrically connected external interconnects, such as solder balls, for mounting and electrically connecting the IC package to a circuit board. Also, in exemplary aspects, the top metallization structure located adjacent to the top IC die can be configured to dominantly provide electrical traces involved in interconnections to the top IC die to minimize the complexity of electrical trace routing in the top metallization structure. The bottom metallization structure located adjacent to the bottom IC die can be configured to dominantly provide electrical traces involved in interconnections to the bottom IC die to also minimize the complexity of electrical trace routing in the bottom metallization structure. Minimizing the complexity of electrical trace routing in the metallization structures could be an important factor in reducing the height of the metallization structures and thus reducing the overall height of the IC package. Die-to-die interconnects can be provided by vi as that extend through available areas in the IC die module and electrically connect to the inside surfaces of the top and bottom metallization structures.

In other exemplary aspects, the split top and bottom metallization structures of the IC package may include redistribution layers (RDLs) that are fabricated according to an RDL fabrication process. An RDL is a distribution of a metal (e.g., copper) pad layer on a dielectric material layer. A second dielectric material layer is formed over the metal layer and then patterned to open up access to the underlying metal layer. A second metal pad layer can be distributed across the second dielectric layer and down into the opening to form an interconnect between the second metal pad layer and the first metal pad layer. The substrate interconnects of the top and bottom metallization structures can be formed by exposed metal layer/pads from respective inside surfaces of the RDL of the top and bottom metallization structures The metallization structures formed by RDL can reduce the electrical resistance of the interconnections between the die interconnects and the substrate interconnects, because the substrate interconnects are formed for a metal layer/pad in the RDL exposed on the inner surfaces of the top and bottom metallization structures. The metal layer/pads formed in the RDLs are more conductive and may have less resistance over other types of interconnects, such as solder balls.

In this regard, in one exemplary aspect, an IC package is provided. The IC package includes a first metallization structure including at least one first interconnect layer. The IC package also includes a second metallization structure including at least one second interconnect layer. The IC package further includes an IC die module disposed between the first metallization structure and the second metallization structure. The IC die module includes a first IC die including a first active surface and a first non-active surface. The IC die module also includes a second IC die including a second active surface and a second non-active surface. The first non-active surface of the first IC die is coupled to the second non-active surface of the second IC die. The first non-active surface of the first IC die is electrically coupled to the at least one first interconnect layer of the first metallization structure. The second non-active surface of the second IC die is electrically coupled to at least one second interconnect layer of the second metallization structure.

In another exemplary aspect, a method of fabricating an IC package is provided. The method includes fabricating a first metallization structure including at least one first interconnect layer. The method also includes fabricating a second metallization structure including at least one second interconnect layer. The method also includes fabricating an IC die module disposed between the first metallization structure and the second metallization structure. The IC die module includes providing a first IC die including a first active surface and a first non-active surface. The IC die module also includes providing a second IC die including a second active surface and a second non-active surface. The method also includes coupling the first non-active surface of the first die to the second non-active surface of the second IC die to couple the first IC die to the second IC die. The method also includes electrically coupling the first active surface of the first IC die to the at least one first interconnect layer of the first metallization structure, and electrically coupling the second active surface of the second IC die to the at least one second interconnect layer of the second metallization structure.

### BRIEF DESCRIPTION OF THE FIGURES

FIG. 1 is a side view of an exemplary flip-chip integrated circuit (IC) package includes semiconductor dice mounted on and electrically coupled to a metallization structure;

FIG. 2 is a side view of an exemplary IC package employing a semiconductor die (“IC die”) module employing stacked IC dice formed between split, double-sided top and bottom metallization structures to provide die-to-die and external interconnections to the IC dice;

FIGS. 3A and 3B are right and left side views of the IC package in FIG. 2 to illustrate additional exemplary detail of the package;

FIGS. 4A and 4B are a flowchart illustrating an exemplary process of fabricating the IC package in FIG. 2;

FIGS. 5A-5H are a flowchart illustrating another exemplary process of fabricating the IC package in FIG. 2 that includes forming the top and bottom metallization structures as redistribution layers (RDLs);

FIGS. 6A-6H illustrate exemplary fabrication stages during fabrication of the IC package in FIG. 2 according to the exemplary process in FIGS. 5A-5H;

FIG. 7 is a block diagram of an exemplary processor-based system that can be provided in one or more IC packages employing a semiconductor die (“IC die”) module employing stacked IC dice formed between split, double-sided top and bottom metallization structures to provide die-to-die and external interconnections to the IC dice, including but not limited to the IC packages in FIGS. 2-3B, and according to the fabrication processes in FIGS. 5A-6H; and

FIG. 8 is a block diagram of an exemplary wireless communications device that includes radio frequency (RF) components provided in one or more IC packages employing a semiconductor die (“IC die”) module employing stacked IC dice formed between split, double-sided top and bottom metallization structures to provide die-to-die and external interconnections to the IC dice, including but not limited to the IC packages in FIGS. 2-3B, and according to the fabrication processes in FIGS. 5A-6H.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed herein include integrated circuit (IC) packages employing split, double-sided metallization structures to facilitate a semiconductor die (“IC die”) module employing stacked dice. Related chip packages and methods of fabricating the IC package are also disclosed. The IC package includes multiple semiconductor dice (also referred to as “IC dice”) mounted on a metallization structure. The metallization structure may be a package substrate or redistributed layers (RDLs) as examples, and can include one or more metal or interconnect layers of electrical traces for signal routing and vertical interconnect accesses (vias) to couple electrical traces together between different layers. Die interconnects (e.g., conductive pads) on a bottom, active surface of the IC die(s) are mounted on and electrically coupled to substrate interconnects exposed on an external surface of a metallization structure to electrically couple the IC die to the electrical traces in a metallization structure. The metallization structure includes one or more dielectric layers that contain a routing layer of electrical traces that can be electrically coupled to electrical traces in an adjacent dielectric layer through vertical interconnect accesses vias) External package interconnects, such as solder balls, are provided on an external surface of a metallization structure and mounted to a circuit board to provide external electrical signal access to IC dice.

In exemplary aspects, to facilitate shrinking the overall height of the IC package to conserve area, the multiple IC dice in the IC package are stacked and bonded together in a back-to-back, top and bottom IC die configuration in an IC die module in the IC package. However, this orients the active areas of the stacked IC dice on opposite sides of the IC die module. Thus, to facilitate die-to-die and external electrical connections to the IC dice stacked in the back-to-back configuration, the metallization structure of the IC package is split between separate top and bottom metallization structures adjacent to respective top and bottom surfaces of the IC die module. The top metallization structure has an inside surface that has exposed substrate interconnects for electrical connection to die interconnects on the top side of the bottom IC die. The bottom metallization structure also has an inside surface that has exposed substrate interconnects for electrical connection to die interconnects on the bottom side of the top IC die. The metallization structures of the IC package being split between the top and bottom metallization structures mounted on opposing sides of the IC die module may allow the combined thickness of the top and bottom metallization structures to be reduced without risking warpage or mechanical instability. The thickness of a single metallization structure in an IC package having IC dice mounted to opposite sides of the single metallization structure may require additional dielectric layers, thus leading to an overall thicker metallization structure to avoid warpage or mechanical instability. The metallization structures of the IC package being split between the top and bottom metallization structures mounted on opposing sides of the IC die module also provides a symmetrical structure for the IC package and IC die module.

In other exemplary aspects, the top and bottom metallization structures are double-sided in that both also include exposed substrate interconnects on their respective outside surfaces that can be electrically connected external interconnects, such as solder balls, for mounting and electrically connecting the IC package to a circuit board. Also, in exemplary aspects, the top metallization structure located adjacent to the top IC die can be configured to dominantly provide electrical traces involved in interconnections to the top IC die to minimize the complexity of electrical trace routing in the top metallization structure. The bottom metallization structure located adjacent to the bottom IC die can be configured to dominantly provide electrical traces involved in interconnections to the bottom IC die to also minimize the complexity of electrical trace routing in the bottom metallization structure. Minimizing the complexity of electrical trace routing in the metallization structures could be an important factor in reducing the height of the metallization structures and thus reducing the overall height of the IC package. Die-to-die interconnects can be provided by vias that extend through available areas in the IC die module and electrically connect to the inside surfaces of the top and bottom metallization structures.

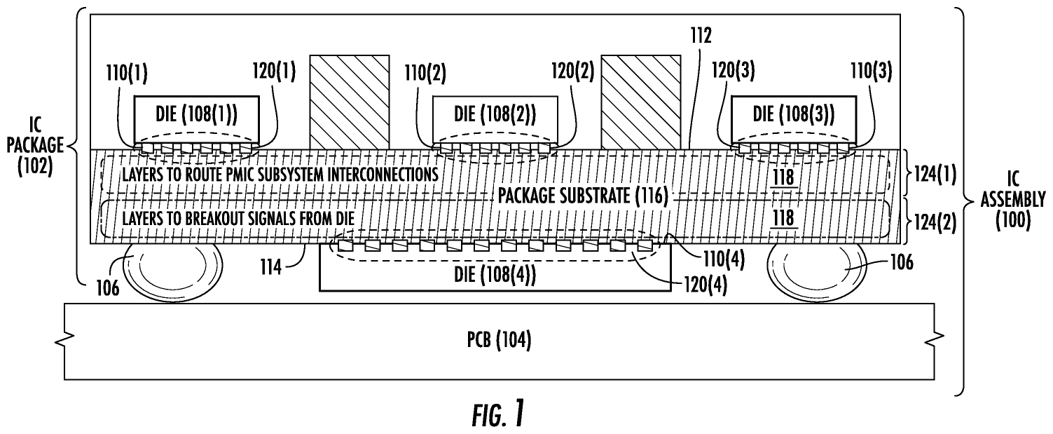

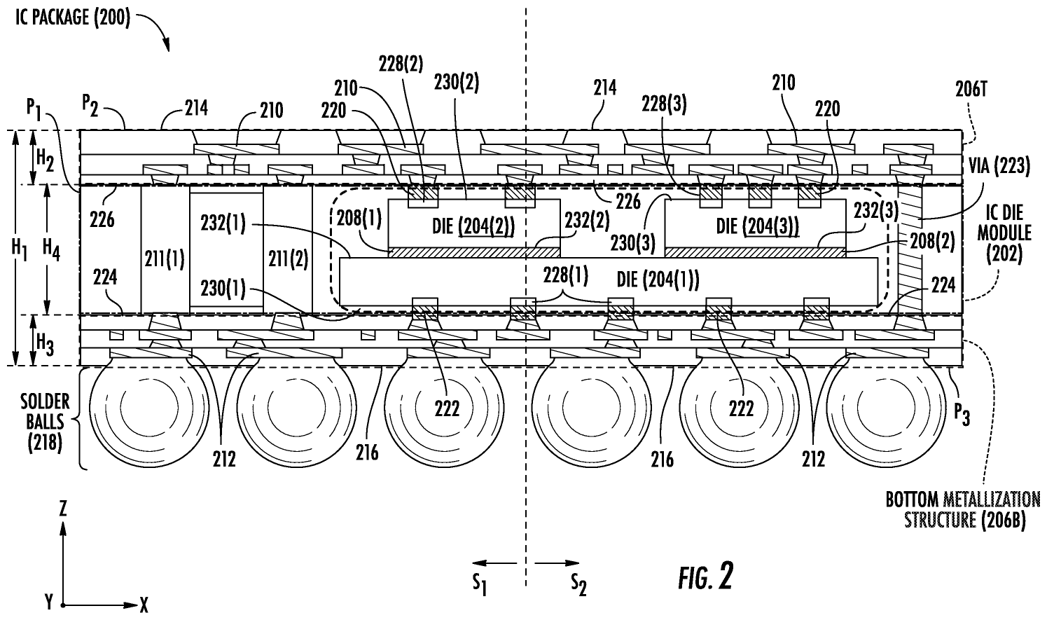

Before discussing examples of IC packages employing split, double-sided metallization structures to facilitate an IC die module employing stacked dice starting at FIG. 2, a flip-chip IC package that employs a common package substrate oriented between opposing IC dice mounted on opposing sides of the package substrate is first described in FIG. 1 below.

In this regard, FIG. 1 illustrates a schematic view of a cross-section of an IC assembly 100 that includes a flip-chip IC package 102 (“IC package 102”) that is mounted to a printed circuit board (PCB) 104 using solder balls 106. The IC package 102 includes multiple semiconductor dice (“IC dice”) 108(1)-108(4) that have respective front surfaces 110(1)-110(4) (i.e., active surfaces) that are mounted to respective front and bottom surfaces 112, 114 of a package substrate 116 via a die-to-die bonding and/or underfill adhesive. For example, the IC dice 108(1)-108(3) could be power management ICs (PMICs) that provide power management related functions. The IC die 108(4) could be an application IC die, such as a processor, as an example. The solder balls 106 are formed on the bottom surface 114 of the package substrate 116 to provide an electrical interface to the IC dice 108(1)-108(4) when the IC package 102 is mounted to the PCB 104. The package substrate 116 can be an embedded trace substrate (ETS) that includes one or more dielectric layers that include embedded electrical traces 118 (e.g,, copper metal traces) coupled to the solder balls 106 to provide electrical signal routing between the solder balls 106 and the IC dice 108(1)-108(4). The electrical traces 118 in the package substrate 116 are coupled to solder balls 120(1)-120(4) exposed from the front and bottom surfaces 112, 114 of the package substrate 116 provide electrical connections to the IC dice 108(1)-108(4). The IC dice 108(1)-108(4) include metal interconnects (e.g., pads) that are coupled to the respective solder balls 120(1)-120(4) when mounted to the package substrate 116 to provide an electrical connect to electrical traces 118 in the package substrate 116 that are routed to the solder balls 106 connected to the PCB 104. Die-to-die electrical connections between the IC dice 108(1)-108(4) can also be made through the coupling of the solder balls 120(1)-120(4) and the electrical traces 118 in the package substrate 116.

With continuing reference to FIG. 1, the package substrate 116 is comprised of a plurality of dielectric layers that may, for example, be laminated together to form the package substrate 116. Electrical traces 118 in different dielectric layers are coupled together through vias (not shown). To reduce routing complexity in the package substrate 116, the package substrate 116 can be designed so that its dielectric layers more involved with providing electrical connections to the IC dice 108(1)-108(4) can be located proximate to the respective IC dice 108(1)-108(4). In this regard, dielectric layer regions 124(1), 124(2) of the package substrate 116 located closer to its front surface 112 and IC dice 108(1)-108(3) can include the electrical traces 118 involved with electrical interconnects to the solder balls 120(1)-120(3) coupled to the IC dice 108(0-108(3). The dielectric layer region 124(2) of the package substrate 116 located closer to its bottom surface 114 and IC die 108(4) can include the electrical traces 118 more involved in providing electrical interconnects to the solder ball 120(4) coupled to the IC die 108(4). Providing a common package substrate 116 that includes electrical routing for electrical connections for all the IC dice 108(1)-108(4) can allow the package substrate 116 to be fabricated separately from the IC dice 108(1)-108(4) in a separate fabrication process for modularity and manufacturing flexibility. However, this may cause a larger number of dielectric layers to be required in the package substrate 116. For example, the package substrate 116 in FIG. 1 may have ten (10) dielectric layers. This can increase the complexity of the fabrication process to fabricate the package substrate 116 and lead to increased fabrication time and associated costs and lower yield.

In this regard, FIG. 2 is a side view of an exemplary IC package 200 employing a semiconductor die (“IC die”) module 202 employing stacked IC dice 204(1)-204(3). The IC die module 202 is disposed in a horizontal plane P₁ in the X-axis and Y-axis directions and is formed between split, double-sided top and bottom metallization structures 206T, 206B to provide die-to-die and external interconnections to the IC dice 204(1)-204(3). The metallization structures 206T, 206B may be a package substrate or redistributed layers (RDLs) as examples, and can include one or more metal or interconnect layers of electrical traces for signal routing and vertical interconnect accesses (vi as) to couple electrical traces together between different layers. The metallization structures 206T, 206B also serve as a support structure in which the IC die module 202 can be disposed on and supported. The metallization structures 206T, 206B may be a package substrate or redistributed layers (RDLs) as non-limiting examples. As discussed in more detail below, the metallization structures 206T, 206B can include interconnect layers that provide external and die-to-die electrical signal routing for the IC dice 204(1)-204(3) in the IC package 200. The top and bottom metallization structures 206T, 206B are disposed in horizontal planes P₂ and P₃ in the X-axis and Y-axis directions and parallel to the horizontal plane P₁ of the IC die module 202. As an example, IC die 204(1) could be an application specific die, such as a general processor as an example. One of IC dice 204(2), 204(3) could be a power management IC (PMIC) that controls power management functions for managing power to the IC die 204(1), as another example. Another of the IC dice 204(2), 204(3) could be a specific processor, such as a modem or baseband processor, as another example. As discussed in more detail below, to minimize the overall height H₁ of the IC package 200, as shown in the Z-axis direction in FIG. 2, the IC dice 204(1) and 204(2), 204(3) are bonded (i.e., physically attached directly or indirectly) together in a back-to-back configuration in the IC die module 202. An adhesive 208(1), 208(2) can be used to bond top, non-active surfaces 232(2), 232(3) of IC dice 204(2), 204(3) to the top, non-active surface 232(1) of the IC die 204(1) to bond the respective IC dice 204(2), 204(3) to IC die 204(1). Alternative forms of die bonding, such as pressure bonding and temperature bonding, could also be employed. Minimizing the overall height H₁ of the IC package 200 may be important to maximize use of applications of the IC package 200.

Because the IC dice 204(1) and 204(2), 204(3) are bonded together, the split top and bottom metallization structures 206T, 206B are provided above and below the respective IC dice 204(2), 204(3) and 204(1) to facilitate external electrical signal access to the IC dice 204(1)-204(3) in the IC package 200 and to provide die-to-die interconnections. In this regard, the top and bottom metallization structures 206T, 206B can be embedded trace substrates (ETSs) that include electrical traces in one or more dielectric material layers to provide electrical signal routing. In the IC package 200 in FIG. 2, the top and bottom metallization structures 206T, 206B provide external substrate interconnects 210, 212 exposed through respective top and bottom outer surfaces 214, 216 of the respective top and bottom metallization structures 206T, 206B, to provide electrical signal access to the IC dice 204(1)-204(3) in the IC package 200. For example, solder balls 218 shown in FIG. 2 are electrically connected to the external substrate interconnects 212 in the bottom metallization structure 206B to provide an external interface through the bottom metallization structure 206B to the IC die 204(1). Solder balls could also be provided that are electrically connected to the external substrate interconnects 210 in the top metallization structure 206T to provide an external interface through the top metallization structure 206T to the IC dice 204(2), 204(3).

Note that terms “top” and “bottom” are relative terms and the metallization structure 206T in FIG. 2 is labeled “top” as being oriented above the bottom metallization structure 206B in this example. But also note that the IC package 200 could also be oriented where it is rotated 180 degrees from as shown in FIG. 2 where the bottom metallization structure 206B would be above the top metallization structure 206T. Thus, the terms “top” and “bottom” are relative terms and not meant to imply a limitation about the orientation of one metallization structure 206T to the other metallization structure 206B.

With continuing reference to FIG. 2, the top and bottom metallization structures 206T, 206B also provide die interconnections to the respective IC dice 204(2), 204(3) and 204(1) through internal bottom and top substrate interconnects 220, 222 exposed through respective bottom and top inside surfaces 226, 224 of the respective top and bottom metallization structures 206T, 206B. Die interconnects 228(1)-228(3) (e.g., metal pads) of the respective IC dice 204(1)-204(3) are electrically connected to the internal substrate interconnects 220, 222. The die interconnects 228(1) of the first IC die 204(1) are exposed through a bottom, active surface 230(1) of the first IC die 204(1). The die interconnects 228(2) of the second IC die 204(2) are exposed through a bottom, active surface 230(2) of the second IC die 204(2). The die interconnects 228(3) of the third IC die 204(3) are exposed through a bottom, active surface 230(3) of the third IC die 204(3). The die interconnects 228(1)-228(3) couple the respective IC dice 204(1)-204(3) through the internal substrate interconnects 220, 222 and through the bottom and top metallization structures 206B, 206T to their respective external substrate interconnects 210, 212 to provide external electrical signal access to the IC dice 204(1)-204(3) in the IC package 200. Thus, by the top and bottom metallization structures 206T, 206B both having respective internal bottom and top substrate interconnects 220, 222, and external, top and bottom substrate interconnects 210, 212, the top and bottom metallization structures 206T, 206B are “double-sided.”

The splitting of the metallization structure of the IC package 200 in FIG. 2 between the top and bottom metallization structures 206T, 206B can also facilitate more efficient, less complex routing of the electrical traces in the top and bottom metallization structures 206T, 206B for providing electrical signal access to the respective IC dice 204(2), 204(3) and 204(1). For example, the top metallization structure 206T located above and most closely adjacent to the top IC dice 204(2), 204(3) can be designed to include electrical traces that are dominantly involved in interconnections to, and thus electrical signal routing with, the top IC dice 204(2), 204(3). Note that “top” and “bottom” for the IC dice 204(1)-204(3) are relative terms meaning that top IC dice 204(2), 204(3) are positioned adjacent to the top metallization structure 206T, and the bottom IC die 204(1) is positioned adjacent to the bottom metallization structure 206T.

Similarly, the bottom metallization structure 206B located below and most closely adjacent to the bottom IC die 204(1) can be designed to include electrical traces that are dominantly involved in interconnections to, and thus electrical signal routing with, the bottom IC die 204(1). This allows the electrical traces involved for interconnections and signal routing with the bottom IC die 204(1) to have to be included in the same metallization structure as the electrical traces involved for interconnections and signal routing with the top IC dice 204(1)-204(3). If electrical traces involved for interconnections and signal routing for all the IC dice 204(1)-204(3) were provided in a single metallization structure, additional routing layers may have to be provided in the metallization structure to provide sufficient “white space” avoid interference between electrical traces. These additional routing layers could add additional thickness to the metallization structure thereby increasing the overall height of an IC substrate in an undesired manner.

Also, by providing the split top and bottom metallization structures 206T, 206B in the IC package 200 in FIG. 2, additional mechanical stability may be realized that can result in reduced warpage while minimizing the routing layers in the top and bottom metallization structures 206T. 206B. This is because the top and bottom metallization structures 206T, 206B are fully bonded to the IC die module 202, meaning that the bottom and top inside surfaces 226, 224 of the respective top and bottom metallization structures 206T, 206B are bonded to the IC die module 202. This is in contrast, for example, to an IC package that includes a single metallization structure between IC dice mounted to the opposite top and bottom outer surfaces of the single metallization structure to form an IC package. There would be no intermediate IC die module 202 fully bonded to the single metallization structure in this alternative example. Thus, such an IC package that includes such a single metallization structure may be more susceptible to warpage and/or mechanical instability. Thus, such a single metallization structure may have to include additional dielectric layers to add more mechanical stability and/or avoid or reduce warpage, which then would increase the overall height of such an IC package.

With continuing reference to FIG. 2, the top and bottom metallization structures 206T, 206B of the IC package 200 also facilitate die-to-die interconnections between IC die 204(1) and IC dice 204(2). 204(3) through the internal substrate interconnects 220, 222. A vertical interconnect access (via) 223 can be formed in the IC die module 202 that is electrically coupled to and between internal substrate interconnects 220, 222 of the top and bottom metallization structures 206T, 206B, respectively, to provide electrical signal routing between the top and bottom metallization structures 206T, 206B and to the IC dice 204(1)-204(3) through the respective die interconnects 2281)-228(3). Passive electrical devices 211(1), 211(2), such as inductors or capacitors, can also be formed in the IC die module 202 adjacent to the IC dice 204(1)-204(3) and interconnected to/between substrate interconnects in the top and bottom metallization structures 206T, 206B. Also, for example, other IC packages may provide a single metallization structure between IC dice mounted to the opposite top and bottom outer surfaces of the single metallization structure to form an IC package. However, the thickness of a single metallization structure of such an IC package may have to include additional dielectric layers to avoid warpage or mechanical instability, thus leading to an overall taller IC package than the IC package 200 in FIG. 2 as an example.

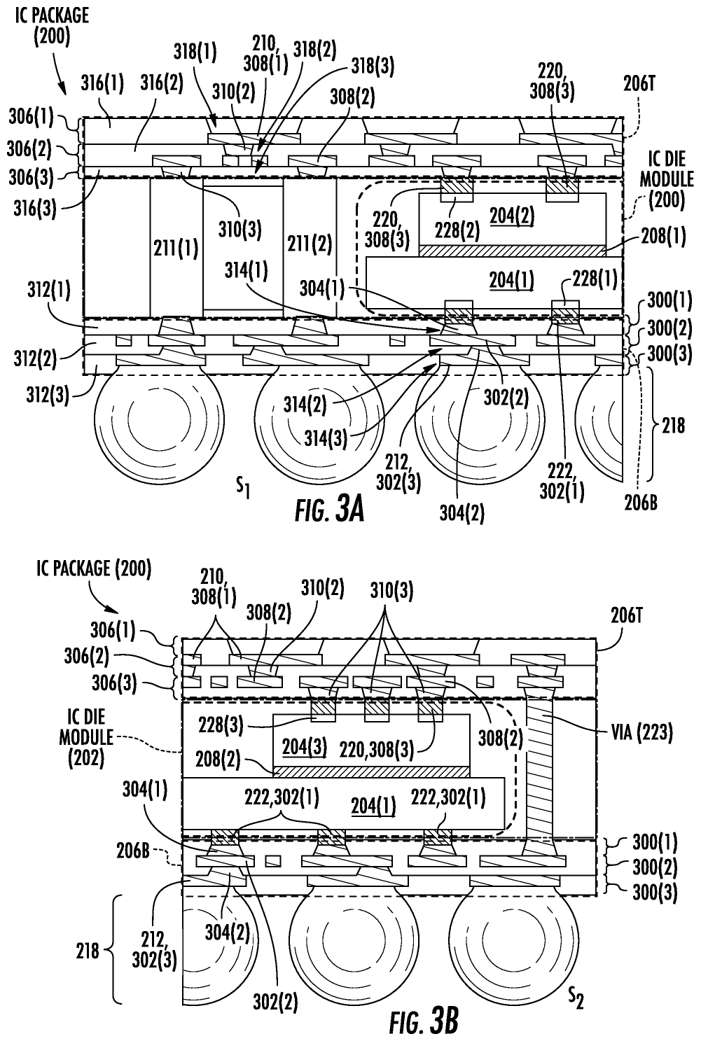

To provide additional exemplary detail regarding the IC package 200 in FIG. 2, FIGS. 3A and 3B are provided. FIG. 3A is a left side view of the IC package 200 in FIG. 2 in section S1 shown in FIG. 2. FIG. 3B is a right side view of the IC package 200 in FIG. 2 in section S2 shown in FIG. 2. As shown in FIGS. 3A and 3B, the IC package 200 includes the bottom metallization structure 206B and top metallization structure 206T. The bottom metallization structure 206B includes multiple interconnect layers 300(1)-300(3) as shown in FIGS. 3A and 3B that are dielectric layers that may be fabricated from a ceramic material in the laminated dielectric layers or fabricated as redistribution layers (RDLs) as examples. The top interconnect layer 300(1) includes the top internal substrate interconnects 222 that are metal contacts 302(1) in this example in contact with vias 304(1). The vias 304(1) are also in contact with metal contacts 302(2) in an intermediate interconnect layer 300(2) between the top and bottom interconnect layers 300(1), 300(3). The metal contacts 302(2) in the interconnect layer 300(2) are also in contact with vias 304(2) in the interconnect layer 300(2). The vias 304(2) are in contact with bottom external substrate interconnects 212 that are metal contacts 302(3) in this example in a bottom interconnect layer 300(3). The metal contacts 302(3) are in electrical contact with the solder balls 218 to provide an external electrical signal interface through the bottom metallization structure 206B to the IC die 204(1). At least one of the metal contacts 302(3) in the interconnect layer 300(3) is electrically coupled to at least one metal contact 302(1) in the interconnect layer 300(1) to provide an external electrical interface between the solder balls 218 and the IC die 204(1). The metal contacts 302(1)-302(3) may be fabricated from copper that has a high conductivity for lower signal routing resistance and higher electrical performance.

With continuing reference to FIGS. 3A and 3B, the IC package 200 also includes the top metallization structure 206T that includes multiple interconnect layers 306(1)-306(3) as shown in FIGS. 3A and 3B that are dielectric layers and may be fabricated from a ceramic material in the laminated dielectric layers or fabricated as RDLs as examples. The top interconnect layer 306(1) includes the top external substrate interconnects 210 that are metal contacts 308(1) in this example in contact with vias 310(2) in an intermediate interconnect layer 306(2) between the top and bottom interconnect layers 306(1), 306(3). The vias 310(2) are also in contact with metal contacts 308(2) in the interconnect layer 306(2). The metal contacts 308(2) in the interconnect layer 306(2) are also in contact with vias 310(3) in the interconnect layer 300(3). The vias 310(3) are in contact with the bottom internal substrate interconnects 220 that are metal contacts 308(3) in this example in interconnect layer 300(3). The metal contacts 308(3) are in electrical contact with the solder balls 218 to provide an external electrical signal interface through the bottom metallization structure 206B to the IC die 204(1). At least one of the metal contacts 308(3) in a bottom interconnect layer 306(3) is electrically coupled to at least one metal contact 308(1) in interconnect layer 300(1) to provide an external electrical interface to the IC dice 204(2), 204(3). The metal contacts 308(1)-308(3) may be fabricated from copper that has a high conductivity for lower signal routing resistance and higher electrical performance.

With reference to FIG. 3B, the via 223 formed in the IC die module 202 is electrically coupled to and between a metal contact 308(3) of an internal substrate interconnect 220 of the top metallization structure 206T and a metal contact 302(1) of an internal substrate interconnect 222 of the bottom metallization structure 206B. The via 223 provides electrical signal routing between the top and bottom metallization structures 206T, 206B and to the IC dice 204(1)-204(3) through the respective die interconnects 228(1)-228(3).

With continuing reference to FIGS. 3A and 3B, the interconnect layers 300(1)-300(3) and 306(1)-306(3) of the bottom and top metallization structures 206B, 2067, respectively, may be RDLs. In this regard, with reference to the interconnect layers 300(1)-300(3) in the bottom metallization structure 206B in FIG. 3B, the bottom interconnect layer 300(3) may include a passivation layer 312(3), such as a dielectric material layer, that is disposed partially below the metal contacts 302(3). The metal contacts 302(3) are disposed in openings 314(3) in the passivation layer 312(3). The intermediate interconnect layer 300(2) may also include a passivation layer 312(2), such as a dielectric material layer, that is disposed partially above the metal contacts 302(2). The vias 304(2) and metal contacts 302(2) are disposed in openings 314(2) in the passivation layer 312(2). The top interconnect layer 300(1) may also include a passivation layer 312(1), such as a dielectric material layer, that is disposed partially above the vias 304(1) and metal contacts 302(1). The vias 304(1) and metal contacts 302(1) are disposed in openings 314(1) in the passivation layer 312(1).

With reference to the interconnect layers 306(1)-306(3) in the top metallization structure 206T in FIG. 3A, the top interconnect layer 306(1) may include a passivation layer 316(1), such as a dielectric material layer, that is disposed partially above the metal contacts 308(1). The metal contacts 308(1) are disposed in openings 318(1) in the passivation layer 316(1). The intermediate interconnect layer 306(2) may also include a passivation layer 316(2), such as a dielectric material layer, that is disposed partially below the metal contacts 308(2). The vias 310(2) and metal contacts 308(2) are disposed in openings 318(2) in the passivation layer 316(2). The bottom interconnect layer 306(3) may also include a passivation layer 316(3), such as a dielectric material layer, that is disposed partially below the vias 310(2) and metal contacts 308(2). The vias 310(3) and metal contacts 308(3) are disposed in openings 318(3) in the passivation layer 316(3).

With reference back to FIG. 2, the respective heights H₂, H₃, and H₄ of the top metallization structure 206T, the bottom metallization structure 206B, and the IC die module 202 can be designed to achieve the overall height H₁ of the IC package 200, as shown in the Z-axis direction. The height H₂ of the top metallization structure 206T, as shown in the Z-axis direction, may be between fifteen (15) micrometers (μm) (1L) and 150 pm (10L) as non-limiting examples. The height H₃ of the bottom metallization structure 206B, as shown in the Z-axis direction, may be between fifteen (15) μm (1L) and 150 μm (10L) as non-limiting examples. The height H₄ of the IC die module 202, as shown in the Z-axis direction, may be between 100 μm and 600 μm as examples. The ratio of the height H₄ of the IC die module 202 to the combined heights H₂+H₃ of the top and bottom metallization structures 206T, 206B may be between 0.33 and twenty (20) as non-limiting examples.

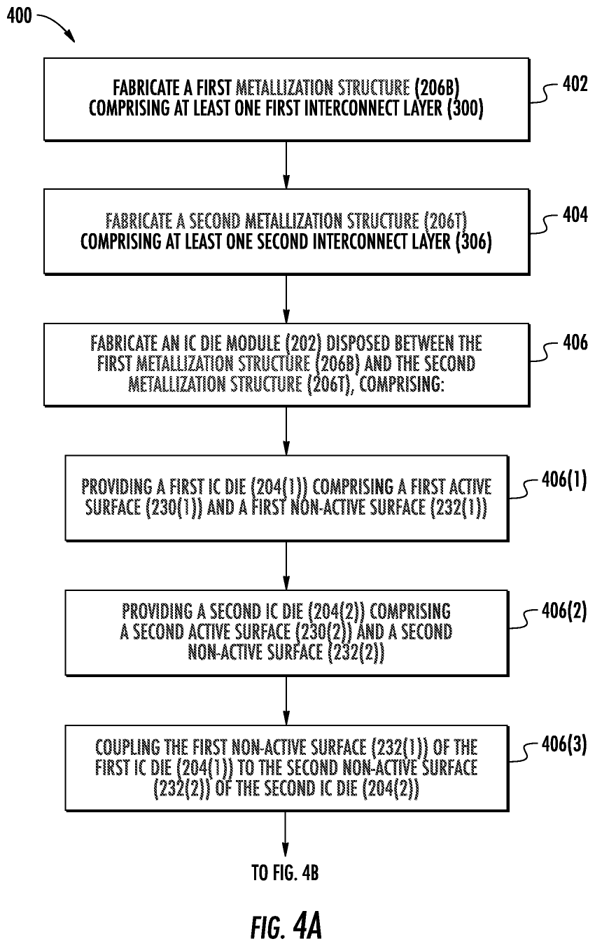

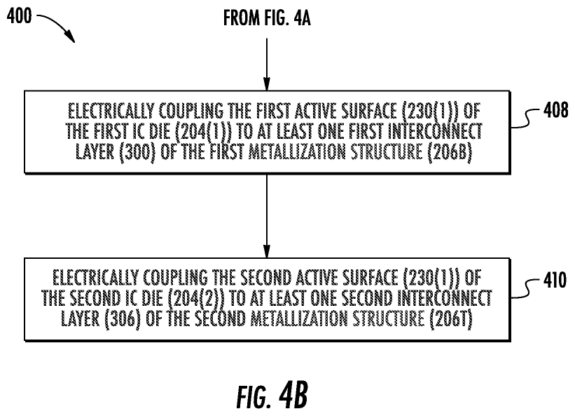

FIGS. 4A and 4B illustrate a flowchart illustrating an exemplary process 400 of fabricating the IC package 200 in FIGS. 2-3B. In this regard, as shown in FIG. 4A, the process 400 includes fabricating a first metallization structure 206B that includes at least one first interconnect layer 300, such as interconnect layers 300(1)-300(3) described above and shown in FIGS. 3A and 3B (block 402 in FIG. 4A). The first metallization structure 206B includes a first top surface 224 and a first bottom surface 216. In the exemplary :IC package 200, the first metallization structure 206B includes one or more first top substrate interconnects 222 exposed through the first top surface 224 of the first metallization structure 206B. The first metallization structure 206B also includes one or more first bottom substrate interconnects 212 exposed through the first bottom surface 216 of the first metallization structure 206B. The first metallization structure 206B also includes at least one of the one or more first top substrate interconnects 222 electrically coupled to at least one first bottom substrate interconnect 212 of the one or more first bottom substrate interconnects 212.

With continuing reference to FIG. 4A, the process 400 also includes fabricating a second metallization structure 206T that includes at least one second interconnect layer 306, such as interconnect layers 306(1)-306(3) described above and shown in FIGS. 3A and 3B (block 404 in FIG. 4A). In the exemplary IC package 200, the second metallization structure 206T includes a second top surface 214 and a second bottom surface 226. The second metallization structure 206T also includes one or more second top substrate interconnects 210 exposed through the second top surface 214 of the second metallization structure 206T. The second metallization structure 206T also includes one or more second bottom substrate interconnects 220 exposed through the second bottom surface 226 of the second metallization structure 206T. The second metallization structure 206T also includes at least one of the one or more second top substrate interconnects 210 electrically coupled to at least one second bottom substrate interconnect 220 of the one or more second bottom substrate interconnects 220.

With continuing reference to FIG. 4A, the process 400 also includes fabricating an IC die module 202 disposed between the first metallization structure 206B and the second metallization structure 206T (block 406 in FIG. 4A), Fabricating the IC die module 202 includes providing the first IC die 204(1) comprising a first active surface 230(1) and a first non-active surface 232(1) (block 406(1) in FIG. 4A). Fabricating the IC die module 202 also includes providing the second IC die 204(2) including a second active surface 230(2) and a second non-active surface 232(2) (block 406(2) in FIG. 4A). Fabricating the IC die module 202 also includes coupling the first non-active surface 232(1) of the first IC die 204(1) to the second non-active surface 232(2) of the second IC die 204(2) (block 406(3) in FIG. 4A). For example, the first non-active surface 232(1) of the first IC die 204(1) and the second non-active surface 232(2) of the second IC die 204(2) can be coupled together in a back-to-back configuration. The first non-active surface 232(1) of the first IC die 204(1) can be bonded to the second non-active surface 232(2) of the second IC die 204(2) to couple the first IC die 204(1) to the second IC die 204(2). With reference to FIG. 4B, fabricating the IC die module 202 also comprises electrically coupling the first active surface 230(1) of the first IC die 204(1) to at least one first interconnect layer 300 of the first metallization structure 206B (block 408 in FIG. 4B). For example, in the IC package 200, electrically coupling the first active surface 230(1) of the first IC die 204(1) to at least one first interconnect layer 300 of the first metallization structure 206B can include electrical coupling at least one of the one or more first die interconnects 228(1) of the first IC die 204(1) to at least one of the one or more first bottom substrate interconnects 222 of the first metallization structure 206B. Fabricating the IC die module 202 also comprises electrically coupling the second active surface 230(1) of the second IC die 204(2) to at least one second interconnect layer 306 of the second metallization structure 206T (block 410 in FIG. 4B). For example, in the IC package 200, electrically coupling the second active surface 230(2) of the second IC die 204(2) to at least one second interconnect layer 306 of the second metallization structure 206T can include electrical coupling at least one of the one or more second die interconnects 228(2) of the second IC die 204(2) to at least one of the one or more first bottom substrate interconnects 220 of the second metallization structure 206T.

As discussed above, the split top and bottom metallization structures 206T, 206B of the IC package 200 in FIG. 2 may include RDLs that are fabricated according to an RDL fabrication process. An RDL is a distribution of a metal (e.g., copper) pad layer on a dielectric material layer. A second dielectric material layer is formed over the metal layer and then patterned to open up access to the underlying metal layer. A second metal pad layer can be distributed across the second dielectric layer and down into the opening to form an interconnect between the second metal pad layer and the first metal pad layer. The substrate interconnects 210, 220 of the top metallization structure 206T and the substrate interconnects 212, 222 of the bottom metallization structure 206B can be formed by exposed metal layer/pads from respective inside surfaces RDL of the top and bottom metallization structures 206T, 206B. The top and bottom metallization structures 206T, 206B substrates formed by RDLs can reduce the electrical resistance of the respective inner substrate interconnects 220, 222 to the die interconnects 228(1)-228(3) of the :IC dice 204(1)-204(3), because the inner substrate interconnects 220, 222 are formed for a metal layer/pad in the RDL exposed on the inner surfaces 224, 226 of the top and bottom metallization structures 206T 206B. The metal layer/pads formed in the RDLs of the top and bottom metallization structures 206T 206B are more conductive and may have less resistance over other types of interconnects, such as solder balls.

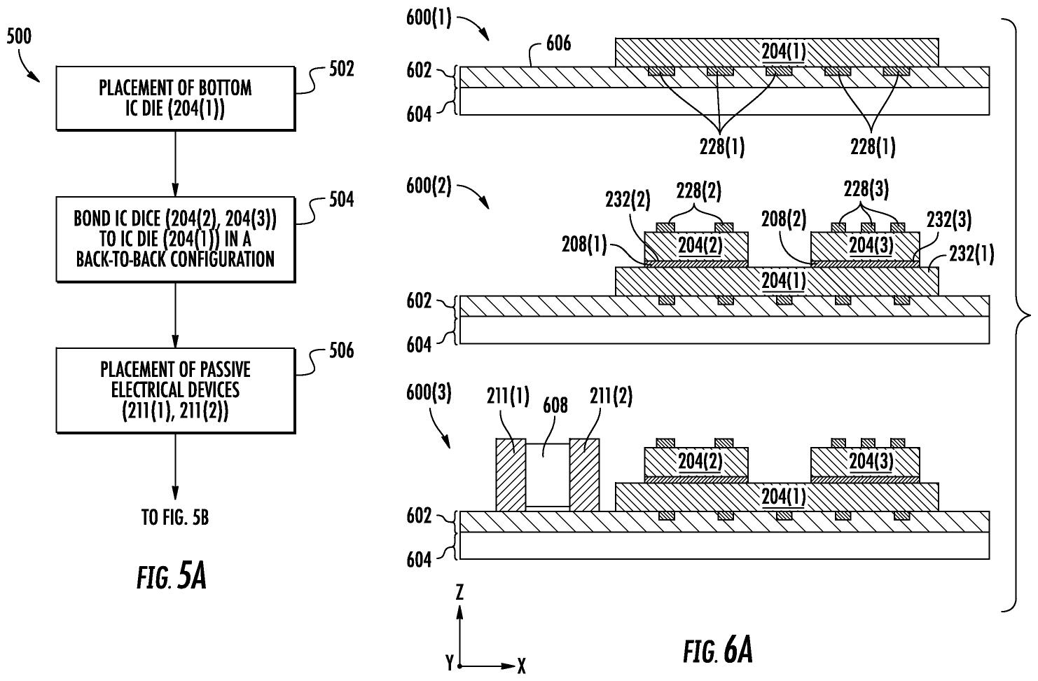

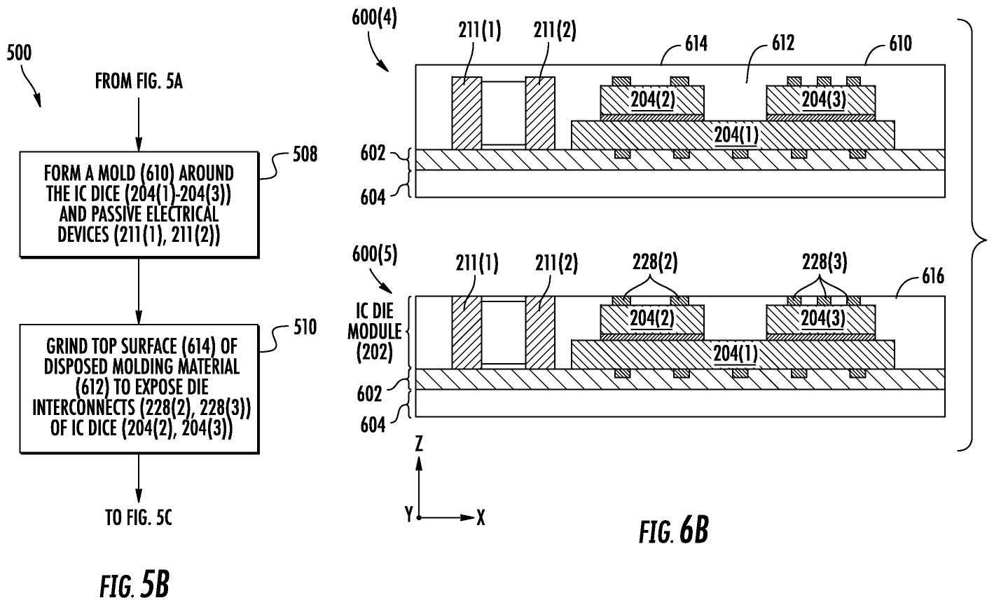

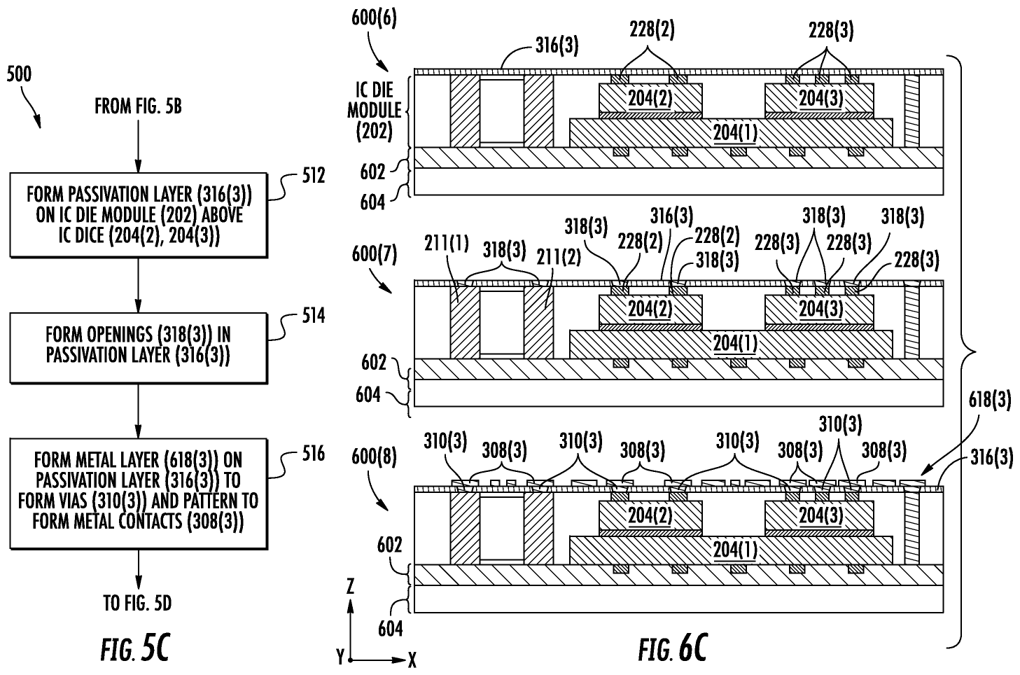

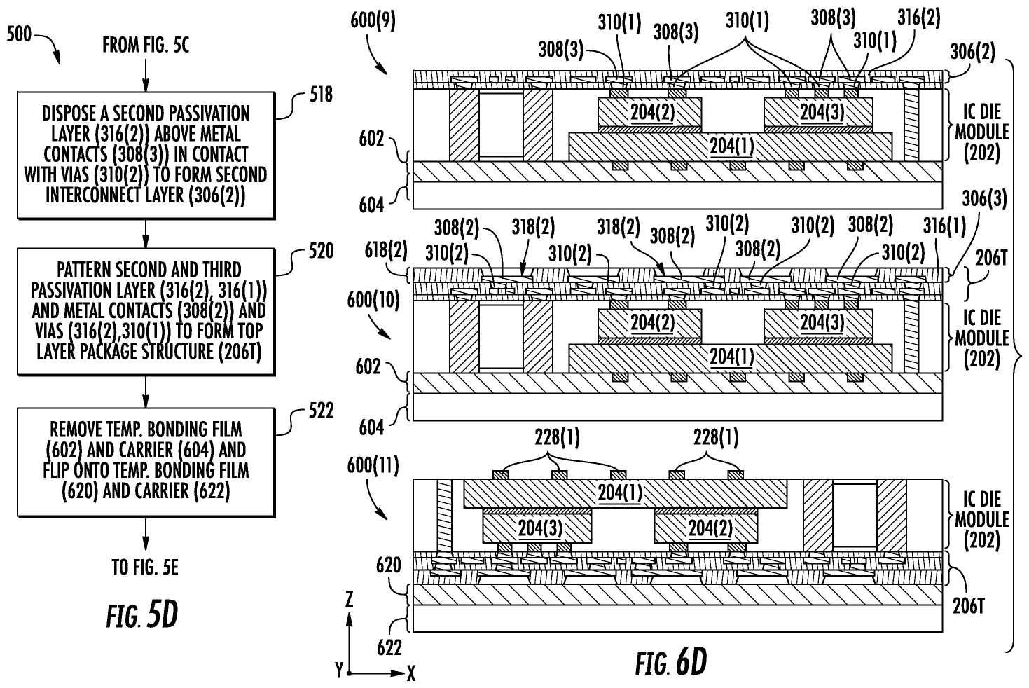

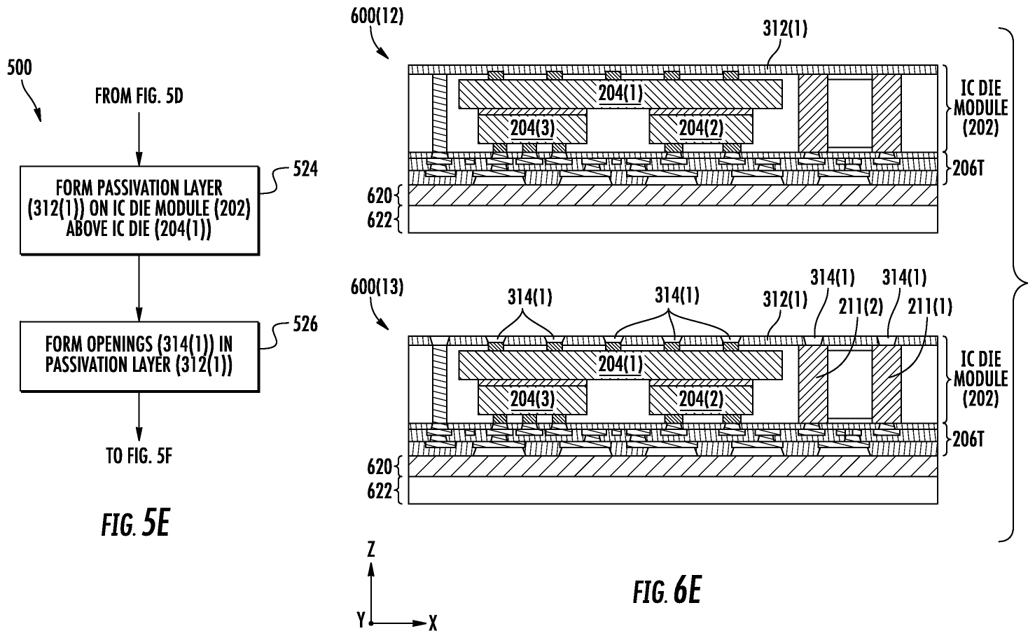

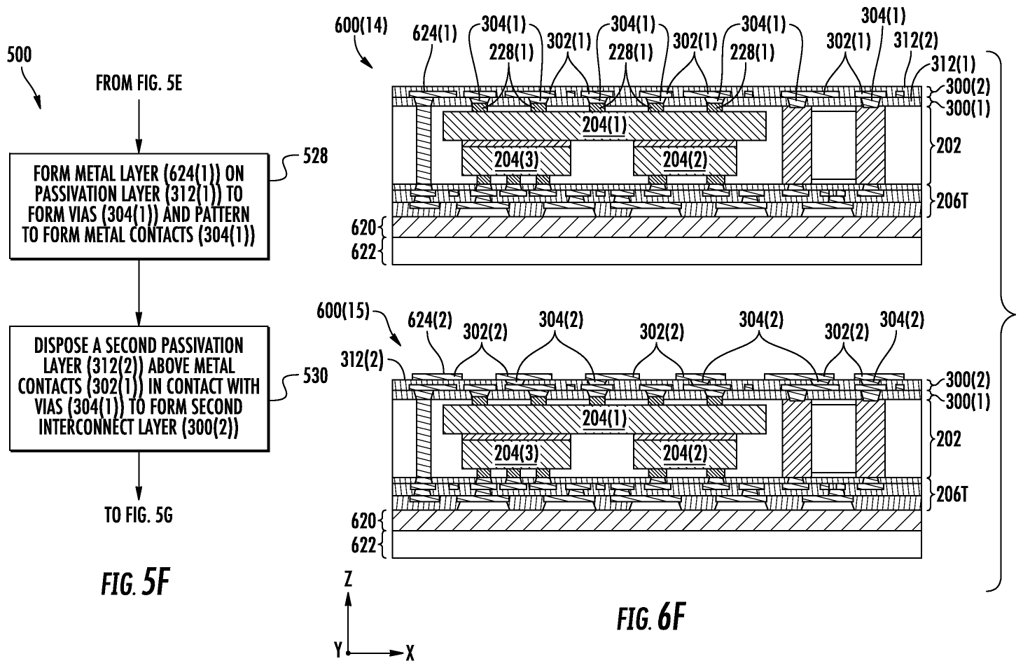

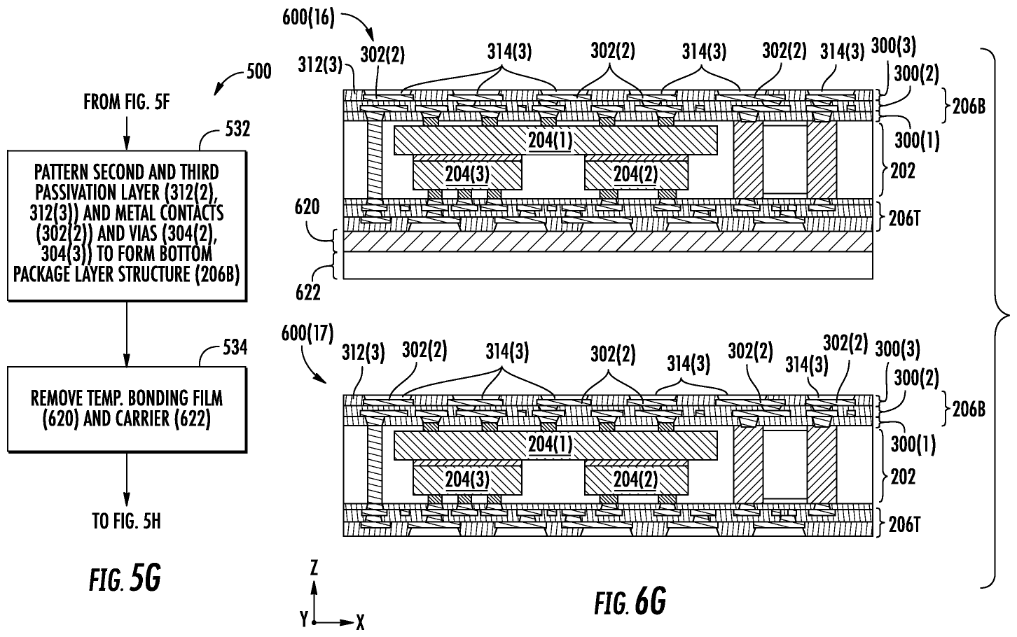

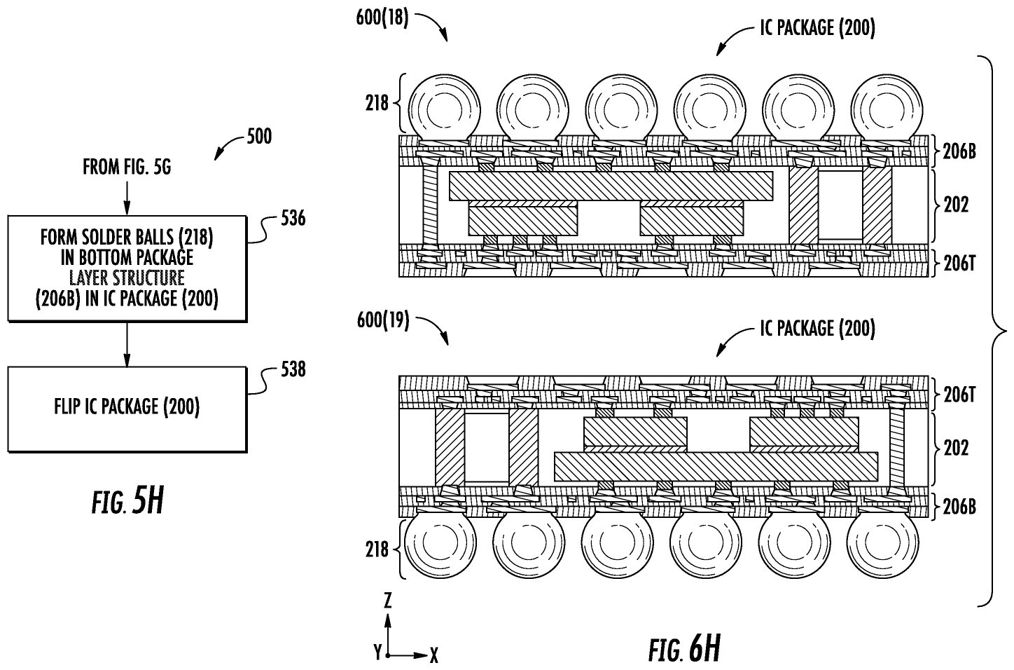

In this regard, FIGS. 5A-5H illustrate a flowchart illustrating an exemplary process 500 of fabricating the IC package 200 in FIG. 2 that includes forming the top and bottom metallization structures 206T, 206B formed as RDLs. FIGS. 6A-6H illustrate exemplary fabrication stages for each of the process steps in FIGS. 5A-5H of the IC package 200 in FIG. 2 as the fabrication process occurs. The process steps in FIGS. 5A-5H and the exemplary related fabrication stages in FIGS. 6A-6H will be described in conjunction.

With reference to FIG. 5A, the process of fabricating the IC package 200 in FIG. 2 includes placement of the bottom IC die 204(1) as part of fabrication the IC die module 202 (block 502 in Figure SA). This is shown in the exemplary fabrication stage 600(1) in FIG. 6A, As shown therein, carrier 604 is provided to handle the eventual placed IC die 204(1) so that the IC die 204(1) can be manipulated during later fabrication stages. A temporary bonding film 602 is formed on the carrier 604. The IC die 204(1) is mounted on a top surface 606 of the temporary bonding film 602. The die interconnects 228(1) of the die 204(1) come into contact with the top surface 606 of the temporary bonding film 602.

A next process step in the fabrication process 500 involves bonding the IC dice 204(2), 204(3) to the IC die 204(1) in a back-to-back configuration (block 504 in FIG. 5A) as part of fabricating the IC die module 202 as shown in the exemplary fabrication stage 600(2) in FIG. 6A. An adhesive 208(1), 208(2) is applied to the top, non-active surface 232(1) of the IC die 204(1). The top, non-active surfaces 232(2), 232(3) of the IC dice 204(2)-204(3) are then brought into contact with the adhesive 208(1), 208(2) to bond the IC dice 204(2), 204(3) to the IC die 204(1) in a back-to-back configuration.

A next process step in the fabrication process 500 involves placing any passive electrical devices 211(1), 211(2) as part of fabricating the IC die module 202 (block 506 in FIG. 5A) as shown in the exemplary fabrication stage 600(3) in FIG. 6A. As shown in fabrication stage 600(3) in FIG. 6A, the passive electrical devices 211(1), 211(2) are mounted to the temporary bonding film 602 adjacent to the IC dice 204(1)-204(3) A dielectric spacer 608 may also be formed between the passive electrical devices 211(1), 211(2) to provide insulation between the passive electrical devices 211(1), 211(2).

A next process step in the fabrication process 500 involves forming a mold 610 around the bonded IC dice 204(1)-204(3) and the passive electrical devices 211(1), 211(2) as part of fabricating the IC die module 202 (block 508 in FIG. 5B) as shown in the exemplary fabrication stage 600(4) in FIG. 6B. A molding material 612 is formed around the bonded IC dice 204(1)-204(3) and the passive electrical devices 211(1), 211(2) to form the mold 610, as shown in fabrication stage 600(4) in FIG. 6B. The molding material is a molding compound that is non-conductive. A top surface 614 of the mold is formed as a result of disposing the molding material. As shown in the exemplary fabrication stage 600(5) in FIG. 6B, the top surface 614 of the disposed mold 610 is grinded and/or polished down to a smooth top surface 616 exposing die interconnects 228(2), 228(3) of the IC dice 204(2), 204(3), later forming of the top metallization structure 206T interconnected to the substrate interconnects 228(2), 228(3) of the IC dice 204(2), 204(3) (block 510 in FIG. 5B). At this point in the process, the IC die module 202 is formed.

A next process step in the fabrication process 500 involves fabricating the top metallization structure 206T on the IC die module 202 as RDLs using an RDL process. This is shown in fabrication stages 600(6)-600(11) in FIGS. 6C and 6D. In this regard, as shown in fabrication stage 600(6) in FIG. 6C, a process step to fabricate the top metallization structure 206T involves forming a first passivation layer 316(3) (see also FIG. 3B) above the IC dice 204(2), 204(3). A next step as shown in fabrication stage 600(7) in FIG. 6C as forming the top metallization structure 206T as RDLs is to pattern openings 318(3) in the passivation layer 316(3) (block 514 in FIG. 5C), wherein the openings 318(3) are located above the die interconnects 228(2), 228(3) of the IC dice 204(2), 204(3) and the passive electrical devices 211(1), 211(2). This is so that a later step of disposing a metal layer on the passivation layer 316(3) will cause metal material to be disposed in the openings 318(3) to form the vias 310(3) and then patterned to form metal contacts 308(3) in contact with the vias 310(3) in a first interconnect layer 306(3) of the top metallization structure 206T.

A next process step in the fabrication process 500 of fabricating the top metallization structure 206T on the IC die module 202 involves disposing a metal layer 618(3) on the passivation layer 316(3) and the openings 318(3) to form the vias 310(3) and then patterning the metal layer 618(3) to form metal contacts 308(3) in contact with the vias 310(3) (block 516 in FIG. 5C), as shown in fabrication stage 600(8) in FIG. 6C. Then, as shown in fabrication stage 600(9) in FIG. 6D, a second passivation layer 316(2) is then formed above the metal contacts 308(3) to form a second interconnect layer 306(2) (block 518 in FIG. 5D). Then, as shown in fabrication stage 600(10) in FIG. 6D, the second passivation layer 316(2) is patterned and a second metal layer 618(2) is disposed on the second passivation layer 316(2) to form vias 310(2) (block 520 in FIG. 5D). The fabrication stage 600(10) in FIG. 6D also shows the formation of metal contacts 308(2) after patterning of the second passivation layer 316(2) with openings 318(2) to form the second interconnect layer 306(2). The fabrication stage 600(10) in FIG. 6D also shows the formation of third passivation layer 316(3) above the second metal contacts 308(2) and openings 318(1).

A next process step in the fabrication process 500 is to fabricate the bottom metallization structure 206B on the IC die module 202 to form the IC package 200 in FIG. 2. This involves removing the temporary bonding film 602 and carrier 604 and flipping the IC die module 202 and top metallization structure 206T combined structure on to a second temporary bonding film 620 and carrier 622 as shown in fabrication stage 600(11) in FIG. 6D (block 522 in FIG. 5D). This orients IC die 204(1) at the top above IC dice 204(2), 204(3). Die interconnects 228(1) of IC die 204(1) are exposed. A next step in fabricating the bottom metallization structure 206B as RDLs is shown in fabrication stage 600(12) in FIG. 6E. A passivation layer 312(1) is formed on the IC die module 202 above the IC die 204(1) (block 524 in FIG. 5E). As shown in the fabrication stage 600(13) in FIG. 6E, openings 314(1) are formed in the passivation layer 312(1) (block 526 in FIG. 5E), wherein the openings 314(1) are located above the die interconnects 228(1) of the IC die 204(1) and the passive electrical devices 211(1), 211(2). This is so that a later step of disposing a metal layer on the passivation layer 312(1) will cause metal material to be disposed in the openings 314(1) to form the vias 304(1) and then patterned to form metal contacts 302(l) in contact with the vias 304(3) in a first interconnect layer 300(1) of the bottom metallization structure 206B.

A next process step in the fabrication process 500 of fabricating the bottom metallization structure 206B on the IC die module 202 involves disposing a metal layer 624(1) on the passivation layer 312(1) and the openings 314(1) to form the vias 304(1) and then patterning the metal layer 624(1) to form metal contacts 302(1) in contact with the vias 304(1) (block 528 in FIG. 5F), as shown in fabrication stage 600(14) in FIG. 6F. Then, as also shown in fabrication stage 600(14) in FIG. 6F, a second passivation layer 312(2) is then formed above the metal contacts 302(1) to form a second interconnect layer 300(2) (block 530 in FIG. 5F). Then, as shown in fabrication stage 600(15) in FIG. 6F, the second passivation layer 312(2) is patterned and a second metal layer 624(2) is disposed on the second passivation layer 312(2) to form vias 304(2) (block 532 in FIG. 5G). The fabrication stage 600(15) in FIG. 6F also shows the formation of metal contacts 302(2) after patterning of the second passivation layer 312(2) with openings 314(2) to form the second interconnect layer 300(2). Then, as shown in fabrication stage 600(16) in FIG. 6G, the third passivation layer 312(3) is disposed on the second passivation layer 316(2) and patterned to form openings 314(3) (block 532 in FIG. 5G). The fabrication stage 600(17) in FIG. 6G shows removal of the temporary bonding layer 620 and carrier 622 to form the IC package 200 (block 534 in FIG. 5G). Solder balls 218 can be formed (block 536 in FIG. 5H) in electrical contact with the bottom metallization structure 206B of the IC package 200 as shown in fabrication stage 600(18) in FIG. 6H, and the IC package 200 flipped (block 538 in FIG. 5H) as shown in fabrication stage 600(19) in FIG. 6H.

Note that “top” and “bottom” where used herein are relative terms and are not meant to limit or imply a strict orientation that a “top” referenced element must always be oriented to be above a “bottom” referenced element, and vice versa.

IC packages employing an IC die module employing stacked IC dice formed between split, double-sided top and bottom metallization structures to provide die-to-die and external interconnections to the IC dice, including but not limited to the IC packages in FIGS. 2-3B, and according to the fabrication processes in FIGS. 5-6H, may be provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

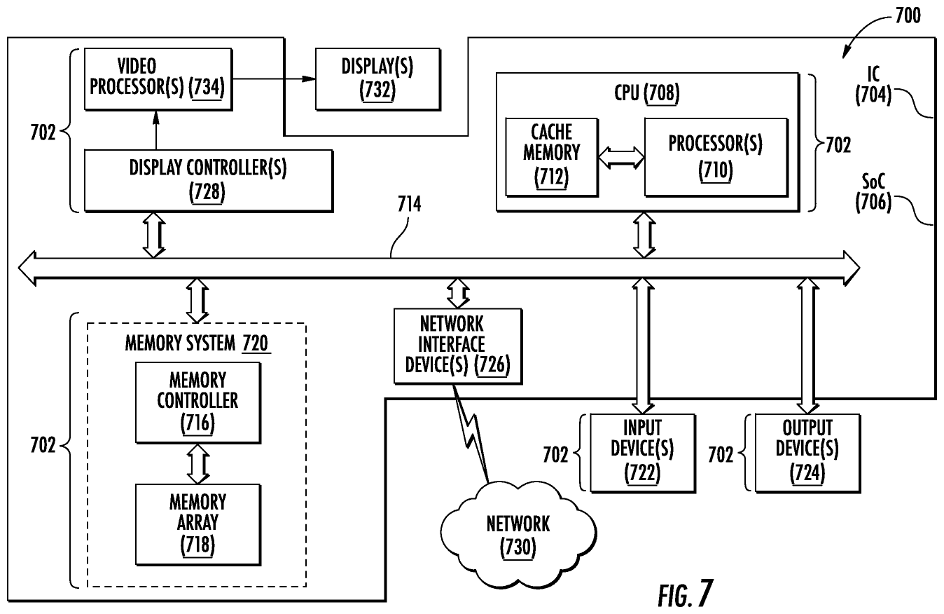

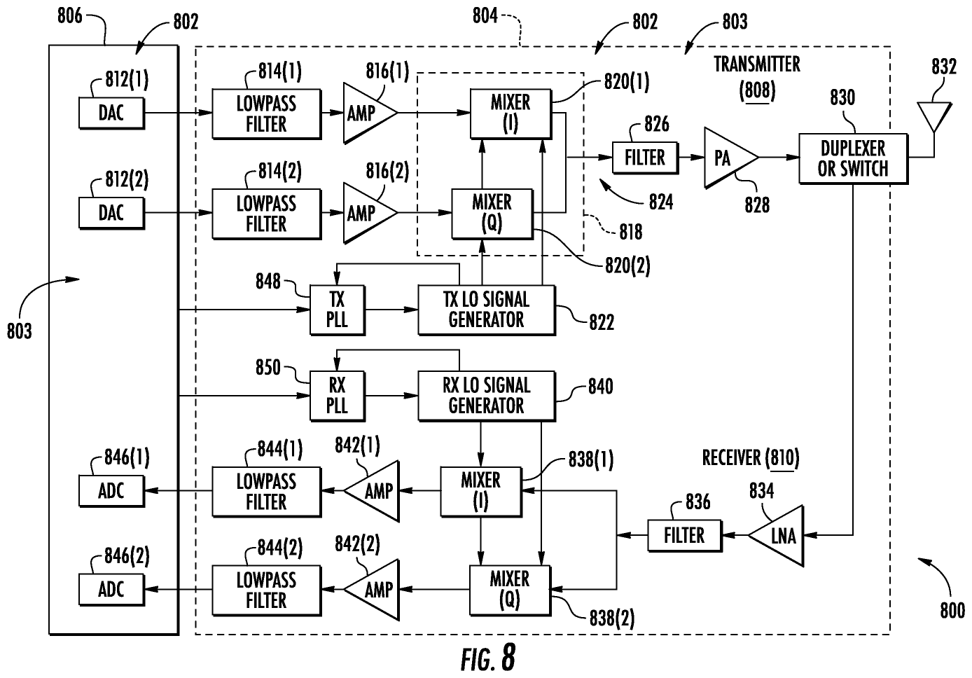

In this regard, FIG. 7 illustrates an example of a processor-based system 700 including a circuit that can be provided in an IC package 702 employing an IC die module employing stacked IC dice formed between split, double-sided top and bottom metallization structures to provide die-to-die and external interconnections to the IC dice, including but not limited to the IC packages in FIGS. 2-3B, and according to the fabrication processes in FIGS. 5A-6H, and according to any aspects disclosed herein. In this example, the processor-based system 700 may be formed as an IC 704 in an IC package 702 and as a system-on-a-chip (SoC) 706. The processor-based system 700 includes a CPU 708 that includes one or more processors 710, which may also be referred to as CPU cores or processor cores. The CPU 708 may have cache memory 712 coupled to the CPU 708 for rapid access to temporarily stored data. The CPU 708 is coupled to a system bus 714 and can intercouple master and slave devices included in the processor-based system 700. As is well known, the CPU 708 communicates with these other devices by exchanging address, control, and data information over the system bus 714. For example, the CPU 708 can communicate bus transaction requests to a memory controller 716 as an example of a slave device. Although not illustrated in FIG. 7, multiple system buses 714 could be provided, wherein each system bus 714 constitutes a different fabric.

Other master and slave devices can be connected to the system bus 714. As illustrated in FIG. 7, these devices can include a memory system 720 that includes the memory controller 716 and a memory array(s) 718, one or more input devices 722, one or more output devices 724, one or more network interface devices 726, and one or more display controllers 728, as examples. Each of the memory system 720, the one or more input devices 722, the one or more output devices 724, the one or more network interface devices 726, and the one or more display controllers 728 can be provided in the same or different IC packages 702. The input device(s) 722 can include any type of input device, including, but not limited to, input keys, switches, voice processors, etc. The output device(s) 724 can include any type of output device, including, but not limited to, audio, video, other visual indicators, etc. The network interface device(s) 726 can be any device configured to allow exchange of data to and from a network 730. The network 730 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 726 can be configured to support any type of communications protocol desired.

The CPU 708 may also be configured to access the display controller(s) 728 over the system bus 714 to control information sent to one or more displays 732. The display controller(s) 728 sends information to the display(s) 732 to be displayed via one or more video processors 734, which process the information to be displayed into a format suitable for the display(s) 732. The display controller(s) 728 and video processor(s) 734 can be included as ICs in the same or different packages 702, and in the same or different IC package 702 containing the CPU 708 as an example. The display(s) 732 can include any type of display, including, but not limited to, a cathode ray tube (CRT), a liquid crystal display (LCD), a plasma display, a light emitting diode (LED) display, etc.

FIG. 8 illustrates an exemplary wireless communications device 800 that includes radio frequency (RF) components formed from one or more ICs 802, wherein any of the ICs 802 can be included in an IC package 803 employing an IC die module employing stacked IC dice formed between split, double-sided top and bottom metallization structures to provide die-to-die and external interconnections to the IC dice, including but not limited to the IC packages in FIGS. 2-3B, and according to the fabrication processes in FIGS. 5A-6H, and according to any aspects disclosed herein. The wireless communications device 800 may include or be provided in any of the above referenced devices, as examples. As shown in FIG. 8, the wireless communications device 800 includes a transceiver 804 and a data processor 806. The data processor 806 may include a memory to store data and program codes. The transceiver 804 includes a transmitter 808 and a receiver 810 that support bi-directional communications. In general, the wireless communications device 800 may include any number of transmitters 808 and/or receivers 81( )for any number of communication systems and frequency bands. All or a portion of the transceiver 804 may be implemented on one or more analog ICs, RF ICs (RFICs), mixed-signal ICs, etc.

The transmitter 808 or the receiver 810 may be implemented with a super-heterodyne architecture or a direct-conversion architecture. In the super-heterodyne architecture, a signal is frequency-converted between RF and baseband in multiple stages, e.g., from RF to an intermediate frequency (IF) in one stage, and then from IF to baseband in another stage for the receiver 810. In the direct-conversion architecture, a signal is frequency-converted between RF and baseband in one stage. The super-heterodyne and direct-conversion architectures may use different circuit blocks and/or have different requirements. In the wireless communications device 800 in FIG. 8, the transmitter 808 and the receiver 810 are implemented with the direct-conversion architecture.

In the transmit path, the data processor 806 processes data to be transmitted and provides I and Q analog output signals to the transmitter 808. In the exemplary wireless communications device 800, the data processor 806 includes digital-to-analog converters (DACs) 812(1), 812(2) for converting digital signals generated by the data processor 806 into the I and Q analog output signals, e.g., I and Q output currents, for further processing.

Within the transmitter 808, lowpass filters 814(1), 814(2) filter the I and Q analog output signals, respectively, to remove undesired signals caused by the prior digital-to-analog conversion. Amplifiers (AMP) 816(1), 816(2) amplify the signals from the lowpass filters 814(1), 814(2), respectively, and provide I and Q baseband signals. An upconverter 818 upconverts the I and Q baseband signals with I and Q transmit (TX) local oscillator (LO) signals through mixers 820(1), 820(2) from a TX LO signal generator 822 to provide an upconverted signal 824. A filter 826 filters the upconverted signal 824 to remove undesired signals caused by the frequency upconversion as well as noise in a receive frequency band. A power amplifier (PA) 828 amplifies the upconverted signal 824 from the filter 826 to obtain the desired output power level and provides a transmit RF signal. The transmit RF signal is routed through a duplexer or switch 830 and transmitted via an antenna 832.

In the receive path, the antenna 83,, receives signals transmitted by base stations and provides a received RF signal, which is routed through the duplexer or switch 830 and provided to a low noise amplifier (LNA) 834. The duplexer or switch 830 is designed to operate with a specific receive (RX)-to-TX duplexer frequency separation, such that RX signals are isolated from TX signals. The received RF signal is amplified by the LNA 834 and filtered by a filter 836 to obtain a desired RF input signal. Downconversion mixers 838(1), 838(2) mix the output of the filter 836 with I and Q RX LO signals (i.e., and LO_I and LO_Q) from an RX LO signal generator 840 to generate l and Q baseband signals. The I and Q baseband signals are amplified by amplifiers (AMP) 842(1), 842(2) and further filtered by lowpass filters 844(1), 844(2) to obtain I and Q analog input signals, which are provided to the data processor 806. In this example, the data processor 806 includes ADCs 846(1), 846(2) for converting the analog input signals into digital signals to be further processed by the data processor 806.

In the wireless communications device 800 of FIG. 8, the TX LO signal generator 822 generates the I and Q TX LO signals used for frequency upconversion, while the RX LO signal generator 840 generates the I and Q RX LO signals used for frequency downconversion. Each signal is a periodic signal with a particular fundamental frequency. A TX phase-locked loop (PLL) circuit 848 receives timing information from the data processor 806 and generates a control signal used to adjust the frequency and/or phase of the TX LO signals from the TX LO signal generator 822. Similarly, an RX PLL circuit 850 receives timing information from the data processor 806 and generates a control signal used to adjust the frequency and/or phase of the RX LO signals from the RX LO signal generator 840.

Those of skill in the art will further appreciate that the various illustrative logical blocks, modules, circuits, and algorithms described in connection with the aspects disclosed herein may be implemented as electronic hardware, instructions stored in memory or in another computer readable medium and executed by a processor or other processing device, or combinations of both. The master and slave devices described herein may be employed in any circuit, hardware component, integrated circuit (IC), or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated. Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

What is claimed is:

1. An integrated circuit (IC) package, comprising:
a first metallization structure comprising at least one first interconnect layer:
a second metallization structure comprising at least one second interconnect layer; and
an IC die module disposed between the first metallization structure and the second metallization structure, the IC die module comprising:
a first IC die comprising a first active surface and a first non-active surface; and
a second IC die comprising a second active surface and a second non-active surface;
the first non-active surface of the first IC die is coupled to the second non-active surface of the second IC die;
the first non-active surface of the first IC die is electrically coupled to the at least one first interconnect layer of the first metallization structure; and
the second non-active surface of the second IC die is electrically coupled to at least one second interconnect layer of the second metallization structure.

2. The IC package of claim I, wherein:
the first metallization structure is disposed in a first horizontal plane;
the second metallization structure is disposed in a second horizontal plane parallel to the first horizontal plane;
the first IC die is disposed in a third horizontal plane parallel to the first horizontal plane; and
the second die is disposed in the second horizontal plane parallel to the first horizontal plane.

3. The IC package of claim I, wherein:
the first metallization structure comprises a first redistribution layer (RDL) structure; and
the second metallization structure comprises a second RDL structure

4. The IC package of claim 1, wherein:
the first metallization structure comprises a first package substrate; and
the second metallization structure comprises a second package substrate.

5. The IC package of claim I, wherein:
the first active surface of the first IC die comprises a first bottom, active surface;
the first non-active surface of the first IC die comprises a first top, non-active surface;
the second active surface of the second. IC die comprises a second bottom, active surface; and
the second non-active surface of the second IC die comprises a second top, non-active surface.

6. The IC package of claim I, wherein:
the first IC die further comprises at least one first die interconnect exposed from the first active surface;
the second IC die further comprises at least one second die interconnect exposed from the second active surface;
the at least one first die interconnect electrically coupled to the at least one first interconnect layer; and
the at least one second die interconnect electrically coupled to the at least one second interconnect layer.

7. The IC package of claim 6, wherein:
the first metallization structure further comprises at least one first substrate interconnect electrically coupled to the at least one first interconnect layer;
the second metallization structure further comprises at least second substrate interconnect electrically coupled to the at least one second interconnect layer;
the at least one first die interconnect is electrically coupled to the at least one first substrate interconnect to be electrically coupled to the at least one first interconnect layer; and
the at least one second die interconnect is electrically coupled to the at least one second substrate interconnect to be electrically coupled to the at least one second interconnect layer.

8. The IC package of claim 1, wherein the first non-active surface of the first IC die is bonded to the second non-active surface of the second IC die.

9. The IC package of claim 2, wherein:
a height of the first metallization structure in a height axis direction perpendicular to the first horizontal plane is between fifteen (15) micrometers (μm) and 150 μm; and
a height of the second metallization structure in the height axis direction perpendicular to the first horizontal plane is between fifteen (15) μm and 150 μm.

10. The IC package of claim 9, wherein a height of the IC die module in the height axis direction perpendicular to the first horizontal plane is between 100 μm and 600 μm.

11. The IC package of claim 2, wherein the ratio of a height of the IC die module in a height axis direction perpendicular to the first horizontal plane, and the combined heights of the first metallization structure and second metallization structure in the height axis direction are between 0.33 and 20.0.

12. The IC package of claim 1, further comprising an adhesive between the first active surface of the first IC die and the second non-active surface of the second IC die to bond the first active surface of the first IC die and the second non-active surface of the second IC die.

13. The IC package of claim 1, wherein:
the IC die module further comprises a third IC die comprising a third active surface and a third non-active surface;
the third non-active surface of the third IC die is coupled to the first non-active surface of the first IC die; and
the third non-active surface of the third IC die is electrically coupled to the at least one second interconnect layer of the second metallization structure.

14. The IC package of claim 1, wherein the IC die module further comprises at least one passive electrical device disposed adjacent to the first IC die and the second IC die;
the at least one passive electrical device electrically coupled to the at least one first interconnect layer of the first metallization structure, and the at least one second interconnect layer of the second metallization structure.

15. The IC package of claim 1, wherein the IC die module further comprises at least one vertical interconnect access via) disposed adjacent to the first IC die and the second IC die;
the at least one via electrically coupled to at least one first interconnect layer of the first metallization structure, and at least one second interconnect layer of the second metallization structure.

16. The IC package of claim 1. further comprising at least one solder bump electrically coupled to at least one first interconnect layer of the first metallization structure.

17. The IC package of claim 1 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.

18. A method of fabricating an integrated circuit (IC) package, comprising:
fabricating a first metallization structure comprising at least one first interconnect layer:
fabricating a second metallization structure comprising at least one second interconnect layer; and
fabricating an IC die module disposed between the first metallization structure and the second metallization structure, comprising:
providing a first IC die comprising a first active surface and a first non-active surface; and
providing a second IC die comprising a second active surface and a second non-active surface;
coupling the first non-active surface of the first IC die to the second non-active surface of the second IC die to couple the first IC die to the second IC die;
electrically coupling the first active surface of the first IC die to the at least one first interconnect layer of the first metallization structure; and
electrically coupling the second active surface of the second IC die to the at least one second interconnect layer of the second metallization structure.

19. The method of claim 18, wherein coupling the first non-active surface of the first IC die to the second non-active surface of the second IC die to couple the first IC die to the second IC die comprises:
forming a temporary bonding layer comprising a top surface;
bonding the first IC die to the top surface of the temporary bonding layer; and
bonding the second non-active surface of the second IC die to the first non-active surface of the first IC die.

20. The method of claim 19, wherein:
bonding the second non-active surface of the second IC die to the first non-active surface of the first IC die comprises disposing an adhesive on the first non-active surface of the first IC die; and
bonding the second non-active surface of the second. IC die to the first non-active surface of the first IC die comprises disposing the second non-active surface of the second IC die on the adhesive on the first non-active surface of the first IC die.

21. The method of claim 18, wherein fabricating the IC die module further comprises disposing a mold material over the first IC die and second IC die.

22. The method of claim 19, wherein fabricating the IC die module further comprises disposing a passive electronic device on the temporary bonding layer adjacent to the first IC die.

23. The method of claim 18, wherein fabricating the st metallization structure comprises:
forming a first passivation layer on the first active surface of the first IC die;
forming one or more first patterned openings in the first passivation layer, at least one of the one or more first patterned openings electrically coupled to the first IC die; and
disposing a first metal layer of a first metal material over the first passivation layer and into the one or more first patterned openings such that at least one first via is formed in the one or more first patterned openings electrically coupled to the at least one first interconnect layer.

24. The method of claim 23, wherein fabricating the second metallization structure comprises:
forming a second passivation layer on the second active surface of the second IC die;
forming one or more second patterned openings in the second passivation layer, at least one of the one or more second patterned openings electrically coupled to the second IC die; and
disposing a second metal layer of a second metal material over the second passivation layer and into the one or more second patterned openings such that at least one second via is formed in the one or more second patterned openings electrically coupled to the at least one second interconnect layer.

25. The method of claim 23, further comprising forming one or more solder balls in electrical contact with the at least one first interconnect layer of the first metallization structure.
